(19) United States
(12) Patent Application Publication
(10) Pub. No.: US 2025/0098063 A1
(43) Pub. Date: Mar. 20, 2025

(54) DISPLAY DEVICE

(71) Applicant: Japan Display Inc., Tokyo (JP)

(72) Inventors: Tatsuya IDE, Tokyo (JP); Takeshi KASHIRO, Tokyo (JP); Yasuhito ARUGA, Tokyo (JP); Yasuhiro KITAMURA, Tokyo (JP); Hiroyuki ONODERA, Tokyo (JP); Kazuto TSURUOKA, Tokyo (JP)

(73) Assignee: Japan Display Inc., Tokyo (JP)

(21) Appl. No.: 18/884,151

(22) Filed: Sep. 13, 2024

(30) Foreign Application Priority Data
Sep. 14, 2023 (JP) 2023-149094

(51) Int. Cl. H05K 1/02

(52) U.S. Cl. CPC H05K 1/028; H05K 2201/10128

(57) ABSTRACT

According to one embodiment, a display device includes a substrate provided with a display area including a plurality of pixels, and an end portion region including a connection portion, a flexible wiring substrate including wiring lines and a flexible base, and a drive IC chip provided on the flexible wiring substrate, and a protective member extending from an end portion of the substrate and overlapping the wiring lines of the flexible wiring substrate, wherein the flexible wiring substrate is bent in a bend region, the drive IC chip opposes the display area, an elastic modulus of the protective member is 10 MPa or more and 20 MPa or less.

### CROSS-REFERENCE TO RELATED APPLICATION

This application is based upon and claims the benefit of priority from Japanese Patent Application No. 2023-149094, filed Sep. 14, 2023, the entire contents of which are incorporated herein by reference.

### FIELD

Embodiments described herein relate generally to a display device.

### BACKGROUND

Flat panel displays, such as organic electro luminescence (EL) displays, have display panels in which a thin film transistor (TFT) or organic light-emitting diode (OLED) is formed on a substrate.

### BRIEF DESCRIPTION OF THE DRAWINGS

FIG. 1 is a perspective view showing a configuration example of a display device according to an embodiment.

FIG. 2 is a diagram showing the display device of FIG. 1 as viewed from a rear surface side.

FIG. 3 is a cross-sectional view showing an example of a brief configuration of a display panel in a comparative example.

FIG. 4 is a cross-sectional view showing an example of a brief configuration of a display panel in a comparative example.

FIG. 5 is a cross-sectional view showing an example of a brief configuration of a display panel in a comparative example.

FIG. 6 is a cross-sectional view showing an example of a brief configuration of a display panel in an embodiment.

FIG. 7 is a diagram illustrating the relationship between a modulus of elasticity of a protective material and a distance that a flexible wiring board protrudes outward from an end portion of a substrate.

FIG. 8 is a partial plan view schematically showing an example of a configuration of a display panel.

FIG. 9 is a cross-sectional view of the display panel shown in FIG. 8 taken along the line A1-A2.

### DETAILED DESCRIPTION

In general, according to one embodiment, a display device comprises
a substrate provided with a display area including a plurality of pixels, and an end portion region including a connection portion;
a flexible wiring substrate including wiring lines and a flexible base; and
a drive IC chip provided on the flexible wiring substrate, and
a protective member extending from an end portion of the substrate and overlapping the wiring lines of
the flexible wiring substrate, wherein the flexible wiring substrate is bent in a bend region,
the drive IC chip opposes the display area,
an elastic modulus of the protective member is 10 MPa or more and 20 MPa or less.

An object of this embodiment is to provide a display device with a narrowed frame.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

With such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Further, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction Z is referred to as cross-sectional view.

### EMBODIMENT

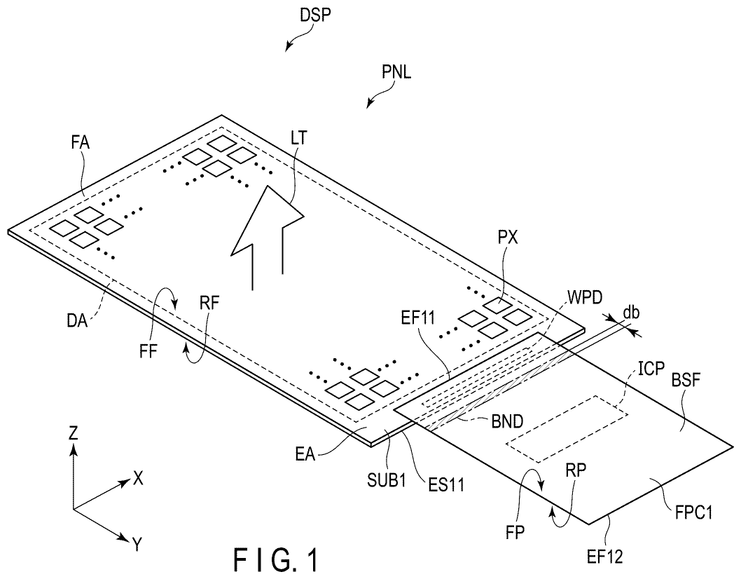

FIG. 1 is a perspective view showing a configuration example of a display device according to this embodiment. The display device DSP shown in FIG. 1 comprises, for example, an active matrix display panel PNL.

The display device DSP comprises a display area DA and a peripheral area FA provided around the display area DA on a substrate SUB1. The display device DSP includes a plurality of pixels PX arranged in the display area DA. In the display device DSP, light LT of each pixel PX is emitted upward.

The surface of the display panel PNL that emits the light LT is referred to as a surface FF. The surface on an opposite side to the surface FF in the third direction Z is referred to as a surface RF. The surface FF may be defined as an emission surface, front surface, or upper surface, and the surface RF may be defined as a rear surface or lower surface.

An area EA of an end portion of the substrate SUB1 is located on an outer side the display area DA. The area EA may as well be referred to as an end portion area of the display panel PNL. The area EA is provided with a connection portion WPD. To the connection portion WPD, wiring lines from the display area DA extend. The wiring lines from the display area DA including scanning lines or signal lines from the pixels PX or wiring lines connected to the scanning lines or the signal lines.

In the connection portion WPD of the area EA, a flexible wiring substrate FPC1 is provided. The flexible wiring substrate FPC1 includes a plurality of wiring lines aligned along the first direction X. The wiring lines of the flexible wiring substrate FPC1 are electrically connected to the connection portion WPD by an anisotropic conductive film (ACF). With this configuration, the wiring lines from the display area DA and the wiring lines of the flexible wiring substrate FPC1 are electrically connected respectively each other.

The end portion of the flexible wiring substrate FPC1 that is close to the connection portion WPD is here referred to as an end portion EF11. The end portion on an opposite side to the end portion EF11 along the second direction Y is referred to as an end portion EF12. The surface of the flexible wiring substrate FPC1 that is on the same side as that of the surface FF is referred to as a surface FP. The surface of the flexible wiring substrate FPC1 that is on the same side as that of the surface RF is referred to as a surface RP.

The flexible wiring substrate FPC1 includes a drive IC chip ICP mounted thereon as a signal supply source that supplies signals necessary to drive the display panel PNL. That is, the flexible wiring substrate FPC1 is a chip-on-film (COF). The end portion EF12 of the flexible wiring substrate FPC1 is extended from the end portion ES11 of the substrate SUB1. The drive IC chip ICP is provided in the extended region.

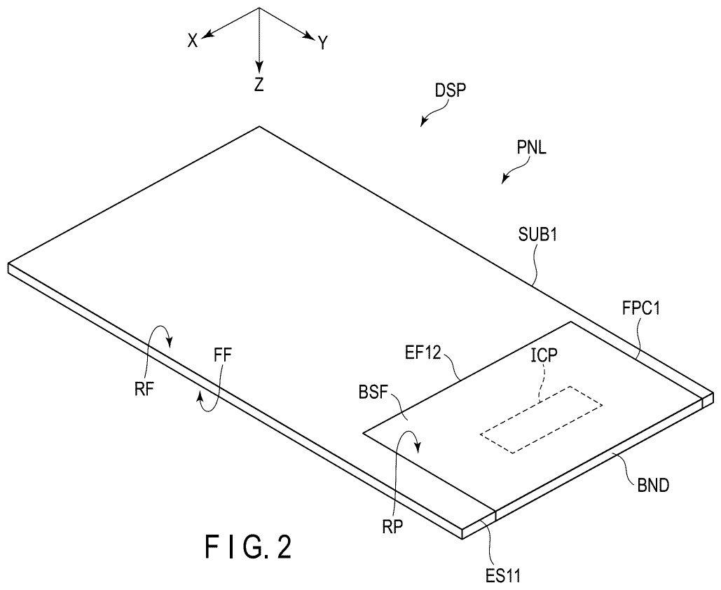

FIG. 2 is a diagram showing the display device shown in FIG. 1 as viewed from the rear surface side. As shown in FIG. 2, the flexible wiring substrate FPC1 of the display device DSP is bent back to a surface RF side, which is the rear surface of the display panel PNL. Of the region of the flexible wiring substrate FPC1, the part bent back to the surface RF side of the display panel PNL is referred to as a bend area BSF.

The length (width) of the bent area BND along the second direction Y is defined as a length db (see FIG. 1). As the bend area BND is smaller, the frame can be made narrower. In other words, as the length db is less, the frame can be made narrower. However, the length db is less, the curvature becomes smaller, which may cause disconnection in the flexible wiring substrate FPC1.

Under these circumstances, in this embodiment, the bend area BND is reinforced by providing a reinforcing resin on the bend area BND.

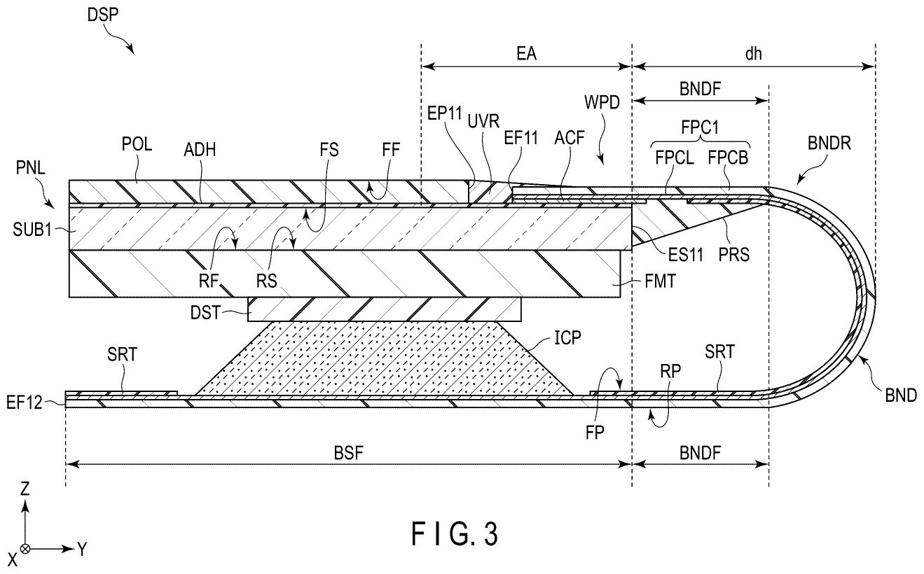

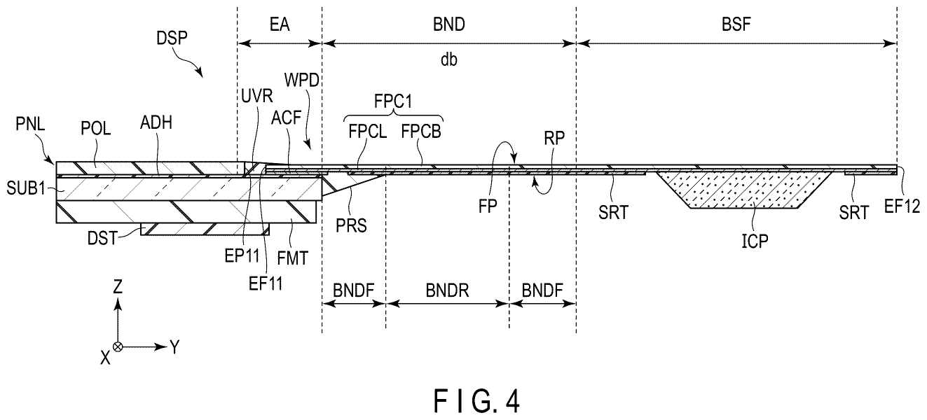

Here, a display device of a comparative example will be described. FIGS. 3 and 4 are cross-sectional views schematically showing an example of a configuration of the display device of the comparative example. FIG. 3 is a cross-sectional view of the display device in a bent state. FIG. 4 is a cross-sectional view of the display device in a state before being bent.

The display device DSP comprises a substrate SUB1, a polarizer POL, an adhesive ADH, an anisotropic conductive film ACF, a flexible wiring substrate FPC1, a protective member UVR, a protective member PRS, a protective member FMT, a protective member DST, a protective member SRT and a drive IC chip ICP.

The substrate SUB1, the polarizer POL, the adhesive ADH, the flexible wiring substrate FPC1, and the drive IC chip ICP constitute a display panel PNL. The flexible wiring substrate FPC1 includes a flexible base FPCB and a wiring line FPCL.

In the display device DSP shown in FIG. 3, the flexible wiring substrate FPC1 is bent in the bend area BND. More specifically, the bend area BND includes a flat region BNDF and a curvature region BNDR. It can as well be said that the bend area BND is a region that protrudes from the end portion ES11 of the substrate SUB1. By bending the flexible wiring substrate FPC1 in the bend area BND, the distance dh in which the substrate SUB1 protrudes outward from the end portion ES11 becomes smaller, and thus the narrowing of the frame can be achieved.

On the substrate SUB1, a polarizer POL is attached by an adhesive ADH. The adhesive ADH is, for example, a transparent optical adhesive. The surface of the polarizer POL, which is on an opposite side to that opposing the substrate SUB1 corresponds to the surface FF of the display panel PNL. The polarizer POL is, for example, a circular polarizer. With the polarizer POL thus provided, for example, the reflection of external light in the display area DA of the display panel PNL can be suppressed.

Of the surfaces of the substrate SUB1, the surface opposing the polarizer POL is referred to as a surface FS. The surface on an opposite side to the surface FS is referred to as a surface RS. The surface RS of the substrate SUB1 corresponds to the surface RF of the display panel PNL.

In the connection portion WPD of the area EA of the substrate SUB1, an anisotropic conductive film ACF is provided. The wiring lines of the substrate SUB1 and the wiring lines FPCL of the flexible wiring substrate FPC1 are electrically connected respectively each other by an anisotropic conductive film ACF.

On the area EA, between the end portion EP11 of the polarizer POL and the end portion EF11 of the flexible wiring substrate FPC1, a protective material UVR is provided.

For the protective member UVR, a photo-curing resin material can be used, for example. The protective member UVR is provided so that there is no gap with respect to the polarizer POL. The protective member UVR is disposed for the purpose of moisture-proof to protect the wiring lines and electrode parts that are not covered by the polarizer POL or the anisotropic conductive film ACF from moisture.

Between the substrate SUB1 and the area BSF of the flexible wiring substrate FPC1, the protective member FMT, the protective member DST, and the drive IC chip ICP are arranged along a direction opposite to the third direction Z.

The protective member FMT is a protective member with a tape provided on front and rear surfaces of its base which has cushioning properties. That is, it can be said that the protective member FMT is a double-sided tape with cushioning properties. The protective member DST is a member with adhesive layers respectively on the front and rear surfaces, that is, for example, a double-sided tape. Note that the protective member DST as well may have cushioning properties.

The protective member FMT and the protective member DST adheres the drive IC chip ICP on the substrate SUB1 and the area BSF on the flexible wiring substrate FPC1. The protective member FMT, with its base with cushioning properties, has a function to keep the interval between the bent flexible wiring substrate FPC1 and the drive IC chip ICP at a certain degree or more. With this structure, even when pressure is applied to the flexible wiring substrate FPC1 in the thickness direction (third direction Z), the curvature of the bend area BND is maintained within an acceptable range.

The protective member SRT is provided so as to be in contact with the wiring lines FPCL of the flexible wiring substrate FPC1. The protective member SRT is formed, for example, of a heat-resistant resin material, more specifically, a so-called solder resist. The protective member SRT is provided in the area where the wiring lines FPCL is provided, except for the region in contact with the anisotropic conductive film ACF and the region in contact with the drive IC chip ICP. The protective member SRT protects the wiring lines FPCL.

The protective member PRS extends from the end portion ES11 of the substrate SUB1 along the second direction Y and overlaps a part of the protective member SRT. A part of the anisotropic conductive film ACF and a part of the wiring lines FPCL are exposed in the vicinity of the end portion ES11 of the substrate SUB1. The protective member PRS protects the exposed part of the anisotropic conductive film ACF and the exposed part of the wiring lines FPCL. If the protective member PRS is not provided, the exposed part of the wiring lines FPCL may be damaged by the end portion ES11 of the substrate SUB1, and the wiring lines FPCL may undesirably break. Further, with the protective member PRS thus provided, the strength of the connection portion WPD can be secured.

It suffices if the protective member PRS is, for example, a resin material. However, when the elastic modulus of the resin material is high, the flexible wiring substrate FPC1 becomes difficult to bend. The length of the flat region BNDF of the bend area BND becomes greater, and the distance dh becomes longer.

Therefore, in this embodiment, a resin material with a low elastic modulus, for example, a resin material having a modulus of an elasticity of 10 MPa or higher to 20 MPa or less, is used as the protective member PRS. When a resin material with such a low elastic modulus is used, the protective member PRS can be crushed so as to be bendable together with the flexible wiring substrate FPC1 when the flexible wiring substrate FPC1 is bent. With this configuration, it is possible to reduce the distance dh in which the flexible wiring substrate FPC1 protrudes outward from the end portion ES11. In this manner, the frame of the display device DSP can be made narrower.

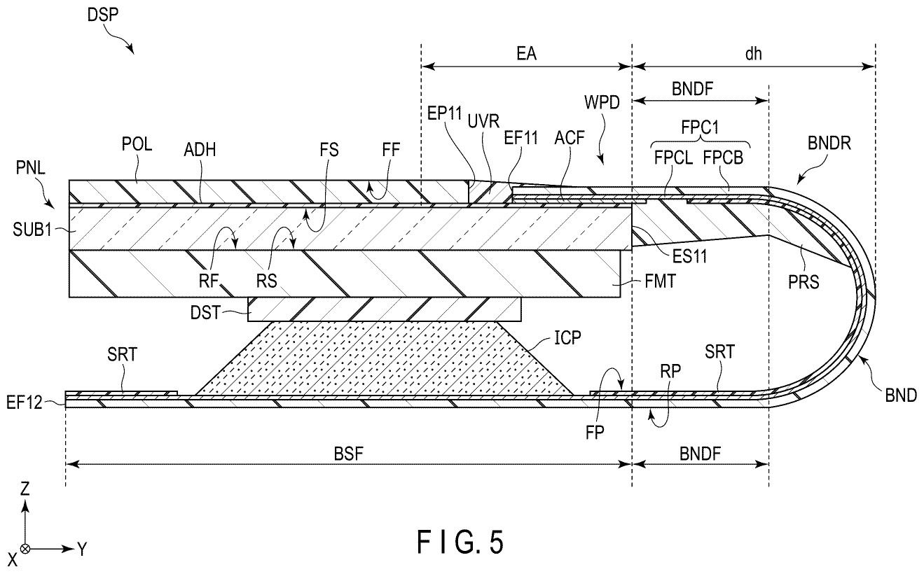

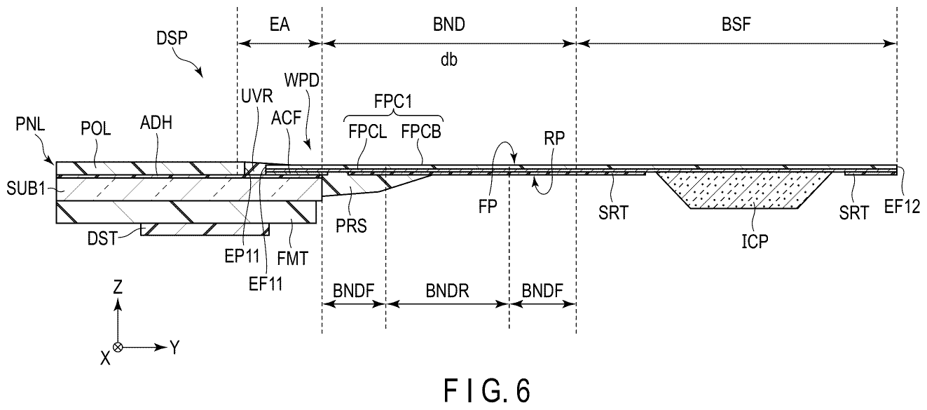

FIGS. 5 and 6 are cross-sectional views schematically illustrating an example of a configuration of a display device of an embodiment. FIG. 5 is a cross-sectional view of the display device in a bent state. FIG. 6 is a cross-sectional view of the display device in a state before being bent. The display device shown in FIGS. 5 and 6 is different from the display device shown in FIGS. 3 and 4 in that the protective member PRS uses a resin material with a low elastic modulus.

The display device DSP shown in FIGS. 5 and 6 is the same as the display device DSP shown in FIGS. 3 and 4 except that the protective member PRS uses a resin material with a low elastic modulus. Therefore, the descriptions of the display device DSP shown in FIGS. 5 and 6 other than the protective member PRS will be omitted, but in place, the explanations with reference to FIGS. 3 and 4 can be applied.

The protective member PRS of the comparative example (see FIG. 3) is provided in the flat region BNDF of the area BND. On the other hand, the protective member PRS of the present embodiment (see FIG. 5) is extended so as to overlap not only the flat area BNDF but also a part of the curvature region BNDR of the area BND.

Since the protective member PRS of this embodiment is formed of a resin material having a low elastic modulus, the protective member PRS is crushed and bent together when the flexible circuit board FPC1 is bent, as described above. On the other hand, since the protective member PRS of the comparative example has a high elastic modulus, it is not bent together when the flexible circuit board FPC1 is bent. Therefore, the protective member PRS of the comparative example is not provided in the curvature region BNDR.

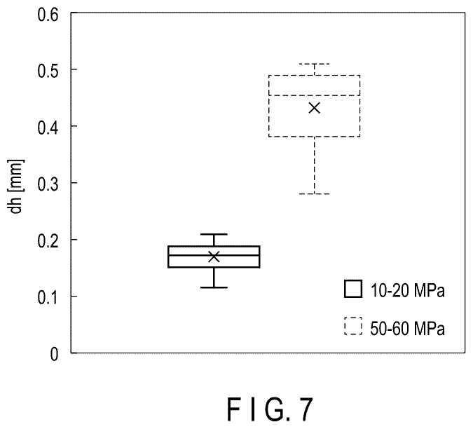

FIG. 7 is a diagram showing the relationship between the elastic modulus of the protective member and the distance that the flexible wiring substrate protrudes outward from the end portion of the substrate. As shown in FIG. 7, when a resin material with a modulus of an elasticity of 50 MPa or more and 60 MPa or less is used as the protective member PRS, the distance dh is 0.3 mm or more and 0.5 mm or less.

On the other hand, when a resin material with a modulus of elasticity of 10 MPa or more and 20 MPa or less is used as the protective member PRS, the distance dh is 0.1 mm or more and 0.2 mm or less. Thus, the distance dh protruding from the end portion ES11 of the substrate SUB1 becomes less, the frame of the display device DSP can be made narrower.

Here, the pixels PX of the display panel PNL will be described in more detail.

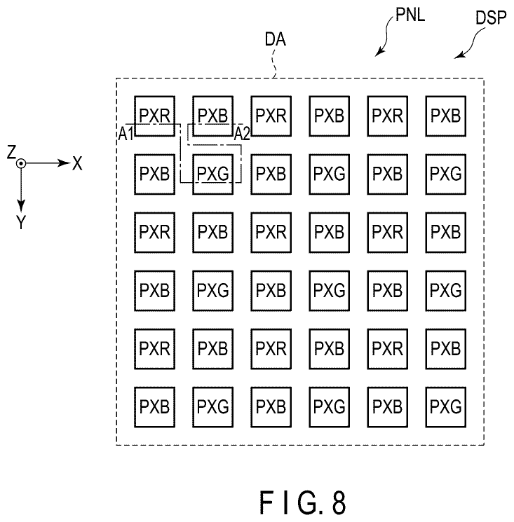

FIG. 8 is a partial plan view schematically showing an example of the configuration of the display panel. The plurality of pixels PX include pixels PXR which emit red color, pixels PXG which emit green color, and pixels PXB which emit blue color. The pixels PXR, pixels PXG, and pixels PXB may as well be referred to as first pixels, second pixels, and third pixels, respectively. The pixels PXR are each disposed adjacent to the respective pixel PXB along the first direction X and the second direction Y. The pixels PXG are each disposed adjacent to the respective pixel PXB along the first direction X and the second direction Y. The pixels PXB are each disposed adjacent to the respective pixel PXR along the first direction and adjacent to the respective pixel PXG along the second direction Y.

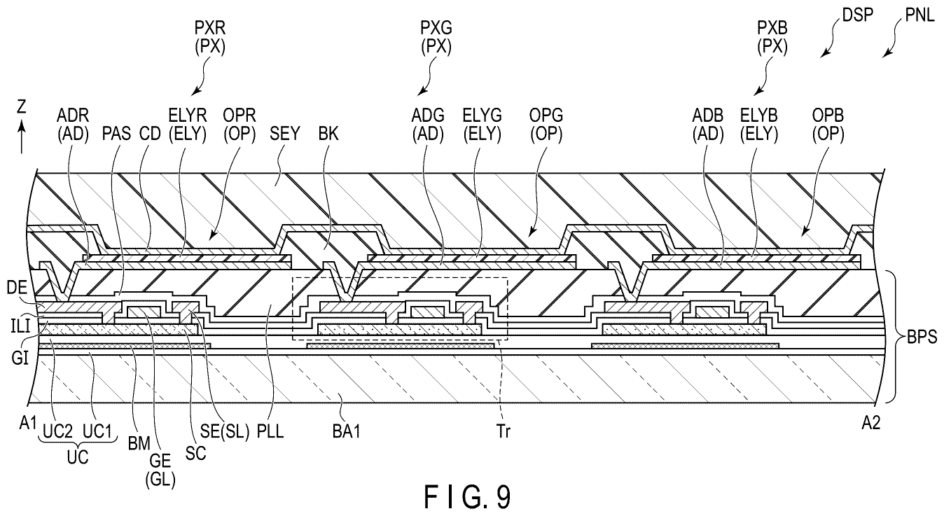

FIG. 9 is a cross-sectional view of the display panel shown taken along line A1-A2 in FIG. 8.

The base BA1 is a base having insulating properties, for example, glass.

On the base BA1, an insulating layer UC1 is provided. The insulating layer UC1 is formed from, for example, a single layer of each of or a stacked layer of a silicon oxide film and a silicon nitride film.

On the insulating layer UC1, a light-shielding layer BM may be provided so as to overlap a transistor Tr. The light-shielding layer BM suppresses changes in transistor characteristics due to light penetration and the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. A material similar to that of the insulating layer UC1 can be used for the insulating layer UC2. The insulating layer UC2 can be made of a material different from that of the insulating layer UC1. For example, silicon oxide can be used for the insulating layer UC1 and silicon nitride can be used for the insulating layer UC2. The insulating layers UC1 and UC2 are collectively referred to as insulating layers UC.

On the insulating layer UC, a transistor Tr is provided. The transistor Tr includes a semiconductor layer SC, an insulating layer GI, a gate electrode GE (scanning line GL), an insulating layer ILI, a source electrode SE (signal line SL) and a drain electrode DE. The transistor Tr is a thin-film transistor (TFT).

As the semiconductor layer SC, amorphous silicon, polysilicon, or oxide semiconductor is used.

As the insulating layer GI, for example, silicon oxide or silicon nitride is provided in a single layer or in a stacked layer.

As the gate electrode GE, for example, a molybdenum-tungsten alloy (MoW) is used. The gate electrode GE may as well be formed to be integrated with the respective scanning line GL.

The insulating layer ILI is provided to cover the semiconductor layer SC and the gate electrode GE. The insulating layer ILI is formed, for example, from a single layer or a stacked layer of a silicon oxide layer and/or silicon nitride layer.

On the insulating layer ILI, a source electrode SE and a drain electrode DE are provided. The source electrode SE and the drain electrode DE are connected to the source region and drain region of the semiconductor layer SC, respectively, via contact holes made in the insulating layer ILI and the insulating layer GI. The source electrode SE may be formed to be integrated with the signal line.

An insulating layer PAS is provided to cover the source electrode SE, the drain electrode DE, and the insulating layer ILI. An insulating layer PLL is provided to cover the insulating layer PAS.

The insulating layer PAS is formed using an inorganic insulating material. Examples of the inorganic insulating material include a single layer of silicon oxide or silicon nitride or a stacked layer thereof. The insulating layer PLL is formed using an organic insulating material. Examples of the organic insulating material include resin insulating materials of polyimide and acrylic. With the insulating layer PLL thus provided, steps caused by the transistor Tr can be planarized.

An anode AD is provided on the insulating layer PLL. The anode AD is connected to the drain electrode DE via contact holes made in the insulating layer PAS and PLL. The anode provided in each pixel PXR is referred to as an anode ADR, the anode provided in each pixel PXB is referred to as an anode ADB, and the anode provided in each pixel PXG is referred to as an anode ADG. When there is no need to distinguish between the anode ADR, the anode ADG, and the anode ADB, they are simply referred to as anodes AD.

The anodes AD, for example, should be formed from a stacked body of a reflective electrode and a transparent electrode. The reflective electrode is formed using a conductive material with high reflectivity, for example, silver (Ag) or aluminum (Al). The transparent electrode is formed using indium tin oxide (ITO) and indium zinc oxide (IZO), for example.

In this embodiment, the configuration from the base BAL to the insulating layer PLL is defined as a backplane BPS.

Between each adjacent pair of anodes AD, a bank BK (which may as well be referred to as a projection portion or rib) is provided. As the material for the bank BK, an organic material similar to the material of the insulating layer PLL is used. The bank BK is opened to expose a part of the anode AD.

The aperture made in each pixel PXR is referred to as an aperture OPR, the aperture made in each pixel PXB is referred to as an aperture OPB, and the aperture made in each pixel PXG is referred to as an aperture OPG. When there is no need to distinguish between the aperture OPR, the aperture OPB, and the aperture OPG, they are simply referred to as apertures OP.

The end portion of the apertures OP should be gently tapered in cross-sectional view. If the end portion of the apertures OP has a steep shape, a coverage error may occur in the organic EL layer ELY, which is to be formed later.

The organic EL layer ELY is provided between each adjacent pair of banks BK so as to overlap the respective anode AD. The organic EL layer ELY includes a hole injection layer, a hole transport layer, an emission layer, an electron transport layer, and an electron injection layer. The organic EL layer ELY may further include an electron blocking layer, and a hole blocking layer, if necessary.

The organic EL layer provided in each pixel PXR is referred to as an organic EL layer ELYR, the organic EL layer provided in each pixel PXB is referred to as an organic EL layer ELYB, and the organic EL layer provided in each pixel PXG is referred to as an organic EL layer ELYG. When there is no need to distinguish between the organic EL layer ELYR, the organic EL layer ELYG, and the organic EL layer ELYB, they are simply referred to as organic EL layers ELY.

A cathode CD is provided on each organic EL layer ELY. The cathode CD is formed, for example, using a magnesium-silver alloy (MgAg) film, a single-layered film of silver (Ag), or a stacked body film of silver (Ag) and a transparent conductive material or the like. For example, indium tin oxide (ITO), indium zinc oxide (IZO) or the like can be used as the transparent conductive material.

An insulating layer SEY is provided to cover the cathodes CD. The insulating layer SEY has the function of preventing moisture from entering the organic EL layer ELY from the outside. As the insulating layer SEY, a material with high gas barrier property is suitable. As the insulating layer SEY, for example, an insulation layer formed by interposing an organic insulating layer between two inorganic insulating layers containing nitrogen can be used. The material of the organic insulating layer can be a resin insulating material of polyimide or acrylic. The material of the inorganic insulating layers containing nitrogen can be, for example, silicon nitride or aluminum nitride.

The light emission generated in the organic EL layer ELY is extracted upward via the respective cathode CD. In other words, the display device DSP (display panel PNL) of this embodiment has a top emission structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a substrate provided with a display area including a plurality of pixels, and an end portion region including a connection portion;
a flexible wiring substrate including wiring lines and a flexible base; and
a drive IC chip provided on the flexible wiring substrate, and
a protective member extending from an end portion of the substrate and overlapping the wiring lines of the flexible wiring substrate, wherein
the flexible wiring substrate is bent in a bend region,
the drive IC chip opposes the display area,
an elastic modulus of the protective member is 10 MPa or more and 20 MPa or less.

2. The display device according to claim 1, wherein
the bend area includes a flat region and a region having curvature, and
the protective member overlaps the area having curvature.

3. The display device according to claim 1, wherein
a double-sided tape having cushioning properties is provided between the drive IC chip and the display area.

4. The display device according to claim 1, wherein
a polarizer is provided on the substrate.

5. The display device according to claim 1, wherein
a heat-resistant resin is provided to cover the wiring lines of the flexible wiring substrate.

6. The display device according to claim 1, wherein
the wiring lines and the connection portion of the flexible wiring substrate are electrically connected to each other by an anisotropic conductive film.
